(19) United States
(12) Patent Application Publication
(10) Pub. No.: US 2026/0164658 A1
(43) Pub. Date: Jun. 11, 2026

(54) SEMICONDUCTOR DEVICE AND FABRICATION METHODS THEREOF

(71) Applicant: Yangtze Memory Technologies Co., Ltd., Wuhan (CN)

(72) Inventors: Hao ZHANG, Wuhan (CN); Kuan DONG, Wuhan (CN); Gang ZHANG, Wuhan (CN); Meng XIAO, Wuhan (CN)

(21) Appl. No.: 19/024,639

(22) Filed: Jan. 16, 2025

(30) Foreign Application Priority Data
Dec. 5, 2024 (CN) 202411786827.X

(51) Int. Cl. H10B 43/27; H01L 21/762; H10B 43/10; H10B 43/35

(52) U.S. Cl. CPC H10B 43/27; H10B 43/10; H10B 43/35; H10W 10/014; H10W 10/17

(57) ABSTRACT

The present disclosure relates to methods, devices, systems, and techniques for managing isolating structures in semiconductor devices. An example semiconductor device includes a stack of conductive layers and isolating layers and a dielectric layer stacked on the stack. The example semiconductor device also includes a first conductive structure having a first end and a second end; a channel structure includes an outer dielectric layer having a first end and a second end. The channel structure includes a channel plug that is partially surrounded by the outer dielectric layer, and the channel structure is connected to the first conductive structure through the channel plug, wherein a length of the first end of a first conductive structure is greater than a length of the first end of the channel structure, the first end of the first conductive structure being farther away from the channel structure than the second end.

### CROSS-REFERENCE TO RELATED APPLICATIONS

This application claims priority to Chinese Patent Application No. 202411786827.X, filed on Dec. 5, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes a stack of conductive layers and isolating layers alternating with each other along a first direction; a dielectric layer stacked on a side of the stack along the first direction; a first conductive structure that extends into the dielectric layer along the first direction, where the first conductive structure includes a first end and a second end opposite to each other; and a channel structure includes an outer dielectric layer that extends through the stack along the first direction, where the channel structure includes a first end and a second end opposite to each other along the first direction, the first end of the channel structure being closer to the first conductive structure than the second end, and where the channel structure includes a channel plug at the first end of the channel structure, where a portion of the channel plug is surrounded by the outer dielectric layer of the channel structure along a second direction perpendicular to the first direction, and the channel structure is connected to the first conductive structure through the channel plug along the first direction, and where a length of the first end of a first conductive structure is greater than a length of the first end of the channel structure along the second direction, the first end of the first conductive structure being farther away from the channel structure than the second end.

In some implementations, a thickness of the dielectric layer is greater than a thickness of the isolating layers of the stack along the first direction.

In some implementations, the semiconductor device further includes an isolation structure that extends through the dielectric layer and at least one conductive layer of the stack along the first direction.

In some implementations, the isolation structure is between two adjacent channel structures along the second direction.

In some implementations, along the second direction, the length of the first end of the first conductive structure is greater than a length of the second end of the first conductive structure, the second end of the first conductive structure being on opposite side of the first end of the first conductive structure along the first direction.

In some implementations, the length of the first end of the channel structure is equal to the length of the second end of the first conductive structure along the second direction.

In some implementations, the semiconductor device includes a second conductive structure having a first end and a second end along the first direction connected to the corresponding channel structure, and where the length of the first end of the first conductive structure is greater than a length of a first end of the second conductive structure along the second direction, the first end of the second conductive structure being farther away from the stack than the second end of the second conductive structure.

In some implementations, the first conductive structure in the dielectric layer is connected to an interconnect structure through a coupling-out structure.

In some implementations, a length of the first end of the first conductive structure is at least two times greater than a length of the coupling-out structure along the second direction.

Another aspect of the present disclosure features a semiconductor device. The semiconductor device includes a stack of conductive layers and isolating layers alternating with each other along a first direction; a dielectric layer stacked on a side of the stack along the first direction; a first conductive structure that extends into the dielectric layer along the first direction, where the first conductive structure includes a first end and a second end opposite to each other; and a channel structure include an outer dielectric layer that extends through the stack along the first direction connected to the first conductive structure, where the channel structure includes a first end and a second end opposite to each other along the first direction, the first end of the channel structure being closer to the first conductive structure than the second end, and where a length of the first end of a first conductive structure is greater than a length of the first end of the channel structure along a second direction perpendicular to the first direction, the first end of the first conductive structure being farther away from the stack than the second end, and where the length of the first end of the channel structure is equal to a length of the second end of the first conductive structure along the second direction, the second end of the first conductive structure being on opposite side of the first end of the first conductive structure along the first direction.

In some implementations, a thickness of the dielectric layer is greater than a thickness of the isolating layers of the stack along the first direction.

In some implementations, the semiconductor device further includes an isolation structure that extends through the dielectric layer and at least one conductive layer of the stack along the first direction, where the isolation structure is between two adjacent channel structures along the second direction.

In some implementations, the channel structure includes a channel plug at the first end of the channel structure, where a portion of the channel plug is surrounded by the outer dielectric layer of the corresponding channel structure along a second direction perpendicular to the first direction, and where the channel structure is connected to the first conductive structure through the channel plug along the first direction.

In some implementations, the semiconductor device includes a second conductive structure having a first end and a second end along the first direction connected to the corresponding channel structure, and where the length of the first end of the first conductive structure is greater than a length of a first end of the second conductive structure along the second direction, the first end of the second conductive structure being farther away from the stack than the second end of the second conductive structure.

In some implementations, the first conductive structure in the dielectric layer is connected to an interconnect structure through a coupling-out structure.

In some implementations, a length of the first end of the first conductive structure is at least two times greater than a length of the coupling-out structure along the second direction.

A further aspect of the present disclosure features a method of forming a semiconductor device. The method includes forming a stack of conductive layers and isolating layers alternating with each other along a first direction; forming a dielectric layer stacked on a side of the stack along the first direction; forming a first conductive structure that extends into the dielectric layer along the first direction, where the first conductive structure includes a first end and a second end opposite to each other; and forming a channel structure include an outer dielectric layer that extends through the stack along the first direction, where the channel structure includes a first end and a second end opposite to each other along the first direction, the first end of the channel structure being closer to the first conductive structure than the second end, and where the channel structure includes a channel plug at the first end of the channel structure, where a portion of the channel plug is surrounded by the outer dielectric layer of the channel structure along a second direction perpendicular to the first direction, and the channel structure is connected to the first conductive structure through the channel plug along the first direction, and where a length of the first end of a first conductive structure is greater than a length of the first end of the channel structure along the second direction, the first end of the first conductive structure being farther away from the channel structure than the second end.

In some implementations, forming the first conductive structure includes forming a stack of sacrificial layers and isolating layers alternating with other along the first direction; depositing a dielectric material on the side of the stack to from the dielectric layer, where the dielectric layer stacked on the side of the stack along the first direction; etching a portion of the dielectric layer and the stack along the first direction to from first space; forming the channel structure in a portion of the first spaces along the first direction, where the channel structure includes a channel plug at the first end of the channel structure; filling a conductive material into a remaining portion of the first space to from the first conductive structure; and replacing a dielectric material in the sacrificial layers with a conductive material to form conductive layers.

In some implementations, the semiconductor device further includes an isolation structure that extends through the dielectric layer and at least one conductive layer of the stack along the first direction, and where forming the isolation structure includes etching through the dielectric layer to form a second space, where the second space is in contact with a corresponding conductive structure; deepening the second space by etching through at least one conductive layer of the stack from an end of the second space along the first direction and etching a portion of the corresponding conductive structure to from a second conductive structure, the end of the second space being connected to the stack; and filling a dielectric material into the second space to form the isolation structure, where the isolation structure is between two adjacent channel structures along the second direction.

In some implementations, the method further includes forming a coupling-out structure, where the first conductive structure in the dielectric layer is connected to an interconnect structure through the coupling-out structure.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIG. 1 illustrates a top view of an example semiconductor device.

FIG. 2A illustrates a top view of an example semiconductor device.

FIG. 2B illustrates a cross-section view of an example semiconductor device of FIG. 2A.

FIG. 2C illustrates a top view of an example semiconductor device of FIG. 2A.

FIGS. 3A-3N show cross-sectional views of structures of a 3D semiconductor device of FIG. 2A at various stages of a fabrication process.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the demand for cheaper memory devices with higher density, a memory device (e.g., a 3D NAND flash memory) can be formed with a large number of layers and a high aspect ratio. The large number of layers and the high aspect ratio of such memory devices may bring challenges to the manufacturing process. For example, the large number of layers requires a larger area for the connection regions of each conductive layer of the memory device, which necessitates additional dummy channel arrays during the fabrication process. In other words, the large area of the connection regions and the additional dummy channel arrays may pose challenges to increasing the density of the memory device. Furthermore, the high density of the memory structure also increases alignment difficulty during the fabrication of the conductive structure. This leads to an increase in alignment errors and requires extra fabrication steps for alignment correction, which leads to a more complex fabrication process. Therefore, fabrication methods that can solve the aforementioned issues are desirable.

In one or more implementations of the present disclosure, an example semiconductor device is provided. The semiconductor device includes a stack of conductive layers and isolating layers alternating with each other along a first direction and a dielectric layer stacked on a side of the stack along the first direction. The semiconductor device also includes a first conductive structure that extends into the dielectric layer along the first direction, where the first conductive structure includes a first end and a second end opposite to each other; and a channel structure include an outer dielectric layer that extends through the stack along the first direction, where the channel structure includes a first end and a second end opposite to each other along the first direction, the first end of the channel structure being closer to the first conductive structure than the second end, and where the channel structure includes a channel plug at the first end of the channel structure, where a portion of the channel plug is surrounded by the outer dielectric layer of the channel structure along a second direction perpendicular to the first direction, and the channel structure is connected to the first conductive structure through the channel plug along the first direction, and where a length of the first end of a first conductive structure is greater than a length of the first end of the channel structure along the second direction, the first end of the first conductive structure being farther away from the channel structure than the second end

Implementations of the present disclosure can provide one or more of the following technical advantages and/or benefits. First, the conductive structure in the present disclosure can be formed by a self-alignment process, which reduces alignment errors and does not require an additional alignment correction step during the fabrication process. Thus, the fabrication process can be simplified by utilizing the fabrication process disclosed in the present disclosure. Second, the isolation structure in the present disclosure can be formed without the requirement of the dummy channel structure. In other words, the isolation structure helps to reduce the area of the connection region, which improves device density. Third, the isolation structure discussed in the present disclosure can be formed on the same deck as the conductive structure, which simplifies the fabrication process. In other words, the conductive structure serves as a mask for the isolation structure, reducing the need for high-resolution lithography tools during the fabrication process.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

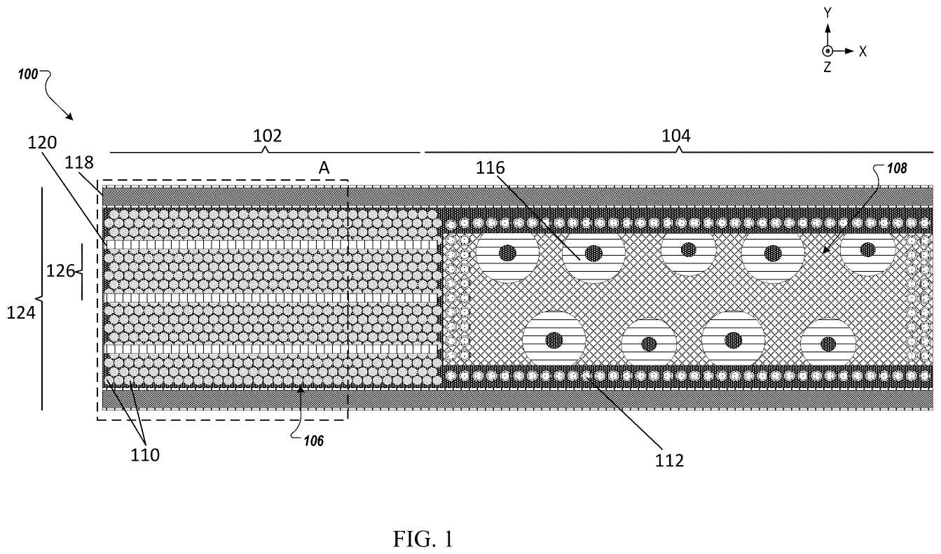

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1, the semiconductor device 100 includes an array region 102 and a connection region 104 adjacent to the array region 102 along a first horizontal direction (e.g., the X direction). It is understood that the example in FIG. 1 is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

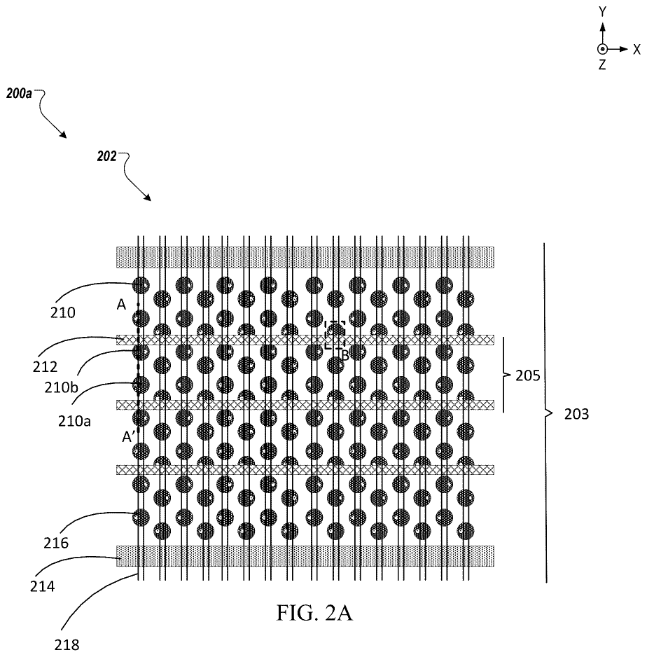

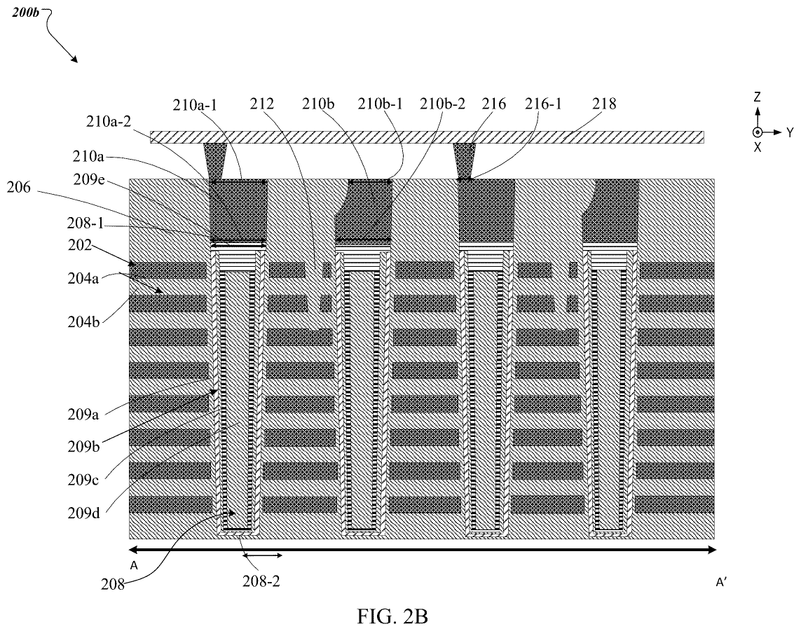

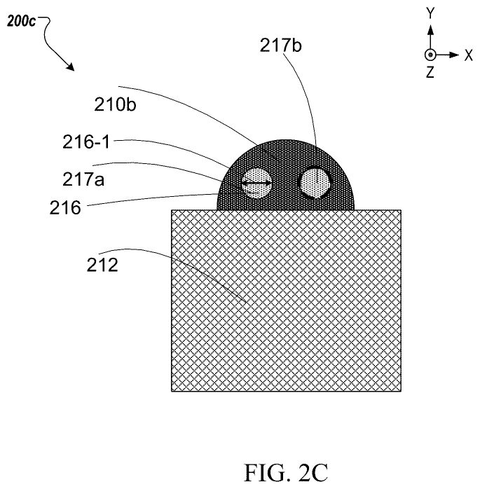

The semiconductor device 100 includes a stack 106 of alternating conductive layers and isolating layers (e.g., conductive layers 204a and isolating layers 204b as shown in FIG. 2B). In some implementations, a part of the stack 106 can be in the array region 102, and another part of the stack 106 can be in the connection region 104. In some implementations, as shown in FIG. 1, the stack 106 can further include a dielectric layer (e.g., the dielectric layer 206 of FIG. 2B) stacked on top of the alternating conductive layers and isolating layers along the Z direction. The semiconductor device 100 further includes a stack 108 of alternating dielectric layers and isolating layers. In some implementations, the stack 108 can be in the connection region 104. The stack 106 is connected to the stack 108.

The semiconductor device 100 can include an array of channel structures (not shown in FIG. 1) extending through the stack 106 in the array region 102. Each channel structure can be used to form a string of memory cells coupled in serial along a vertical direction (e.g., Z direction) perpendicular to the first horizontal direction (e.g., the X direction). In some implementations, as shown in FIG. 1, the semiconductor device 100 can also include conductive structures 110 that extend through the dielectric layer. The conductive structures 110 are connected to the corresponding channel structures of the stack 106 in the array region 102 of the semiconductor device 100. In some implementations, the semiconductor device 100 can include dummy channel structures 112 (also referred to as dummy memory strings) for process variation control during fabrication and/or for additional mechanical support. The dummy channel structures 112 can extend through the stack 106 and/or the stack 108. In some implementations, the dummy channel structures 112 are in the connection region 104. For example, some dummy channel structures 112 can be in the stack 108. In some implementations, the dummy channel structures 112 are in the array region 102 (e.g., an area adjacent to the connection region 104). In some implementations, the dummy channel structures 112 have structures identical or substantially similar to that of the channel structures.

As shown in FIG. 1, the semiconductor device 100 can include contact structures 116 in the connection region 104. A contact structure 116 can be configured to connect a corresponding one of the conductive layers of the stack 106 to a control circuit. The semiconductor device 100 can include one or more gate line structures 118. Each gate line structure 118 can extend in the X direction. The gate line structure 118 can extend into both the array region 102 and the connection region 104. In some implementations, the gate line structures 118 can divide an array region 102 into multiple memory blocks 124. In some implementations, the gate line structure 118 can function as a common source contact for the channel structures in the array region 102. In some implementations (not shown in FIG. 1), the gate line structure 118 can further include one or more segments extending along a second horizontal direction (e.g., the Y direction). In some implementations, the gate line structure 118 can include multiple segments connected in an H shape or a T shape.

The semiconductor device 100 can include isolation structure 120. The isolation structure 120 extends through the dielectric layer and at least one conductive layer of the stack 106 along the Z direction. In some implementations, as shown in FIG. 1, the isolation structure 120 extends along the X direction in the array region 102. In some implementations, the isolation structure 120 is connected to the conductive structures 110 in the array region 102 along a second horizontal direction (e.g., the Y direction) perpendicular to the X direction and the Z direction. In some implementations, the isolation structures 120 extend along the X direction in the array region 102. In some implementations, the isolation structures 120 divided a memory block 124 of an array region 102 into one or more finger 126.

FIG. 2A illustrates a top view of an example semiconductor device 200a zoomed in on zone A of the FIG. 1. As shown in FIG. 2A, the semiconductor device 200a includes a stack 202 of alternating conductive layers and isolating layers (e.g., conductive layers 204a and isolating layers 204b as shown in FIG. 2B). The semiconductor device 200a can include an array of channel structures (e.g., the channel structure 208 of FIG. 2B) extending through the stack 202 along a vertical direction (e.g., the Z direction). In some implementations, the stack 202 can further include a dielectric layer (e.g., the dielectric layer 206 of FIG. 2B) stacked on top of the alternating conductive layers and isolating layers along the Z direction. In some implementations, as shown in FIG. 2A, the semiconductor device 200a can include conductive structures 210 that extend through the dielectric layer. In some implementations, the conductive structures 210 are in contact with the corresponding channel structures 208 of the stack 202 along the Z direction. In some implementations, the conductive structure 210 can be similar to, or same as the conductive structures 110 of the semiconductive device 100 of FIG. 1.

As shown in FIG. 2A, the semiconductive device 200a can include isolation structure 212 extends along a horizontal direction (e.g., the X direction) perpendicular to the Z direction. The isolation structure 212 extends through a portion of the corresponding conductive structure 210 along a second horizontal direction (e.g., the Y direction) perpendicular to the Z direction and the X direction. In some implementations, the isolation structure 212 extends through the dielectric layer 206 and one conductive layer 204a of the stack 202 along the Z direction. In some implementations, the isolation structure 212 can be similar to, or same as the isolation structure 120 of the semiconductor device 100 of FIG. 1. The semiconductor device 200a can include one or more gate line structures 214. Each gate line structure 214 can extend in the X direction and divide the stack 202 into one or more blocks 203. In some implementations, the gate line structure 214 can be similar to, or same as the gate line structure 118 of the semiconductor device 100 of FIG. 1. In some implementations, the isolation structures 212 extend along the X direction in the stack 202. In some implementations, the isolation structures 212 divided a memory block 203 of the stack 202 into one or more finger 205.

In some implementations, the semiconductor device 200a can further include a coupling-out structures 216 connected to the corresponding conductive structure 210 along the Z direction. The coupling-out structures 216 extend in the Y direction. In some implementations, the conductive structures 210 in the dielectric layer 206 are connected to interconnect structures 218 through the coupling-out structure 216. In some implementations, the interconnect structures 218 can be a bit line structure.

FIG. 2B illustrates a cross-sectional view of the semiconductor device 200b along cutline AA′ of the semiconductor device 200a of FIG. 2A. The semiconductor device 200b can be the semiconductor device 200a of FIG. 2A or a structure at an intermediate fabrication process of the semiconductor device 100 of FIG. 1.

As shown in FIG. 2B, the semiconductor device 200b includes a semiconductor layer (not shown in FIG. 2B), the stack 202 of alternating conductive layers 204a and isolating layers 204b. The stack 202 is provided over the substrate. The semiconductor layer can be any suitable semiconductor substrate having any suitable semiconductor material, such as monocrystalline, polycrystalline or single crystalline semiconductor. For example, the substrate can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the semiconductor layer can be removed from the semiconductor device 200b in a later process of manufacturing the semiconductor device 200b.

The conductive layers 204a and the isolating layers 204b can alternate in the vertical direction (e.g., Z direction) perpendicular to the second horizontal direction. The conductive layers 204a can be the same or different from each other in thickness, for example, ranging from 10-500 nm, e.g., about 35 nm. The isolating layers 204b can also be the same or different from each other in thickness, for example, ranging from 10-500 nm, e.g., about 25 nm. It should be noted that the number of the conductive layers 204a and the isolating layers 204b shown in FIG. 2B is for illustration only and that any suitable number of the conductive layers 204a and the isolating layers 204b can be included in the stack 202. The conductive layers 204a can include any suitable conducting material, such as tungsten (W), cobalt (Co), copper (Cu), aluminum (Al), polycrystalline silicon (polysilicon), doped silicon, silicides, or any combination thereof. In some implementations, the isolating layers 204b can include a dielectric material, such as silicon oxide, silicon nitride, silicon oxynitride, or any combination thereof. In some implementations, the isolating layers 204b can also include high-K dielectric materials, such as hafnium oxide, zirconium oxide, aluminum oxide, tantalum oxide, lanthanum oxide, or any combination thereof. In some implementations, a dielectric constant for the high-K dielectric materials (e.g., hafnium oxide) is greater than a dielectric constant of a dielectric material (e.g., Silicon oxide). For example, the high-K dielectric material (e.g., hafnium oxide) has a dielectric constant greater than 20 and a dielectric material (e.g., Silicon oxide) has a dielectric constant of 3.9.

The semiconductor device 200b can include channel structures 208 extending through the stack 202. In some implementations, each channel structure 208 of the channel structures 208 can include a first end 208-1 and a second end 208-2 along the Z direction. Each channel structure 208 can extend through the stack 202 along the Z direction. In some examples, the channel structure 208 can be in the shape of a cylinder or a pillar, and can include an outer dielectric layer 209a, a block layer surrounded by the outer layer, a charge trapping layer (or a storage layer) surrounded by the block layer, a tunneling layer surrounded by the charge trapping layer, a channel layer 209c surrounded by the tunneling layer, and a core filler layer 209d surrounded by the channel layer 209c, and a channel plug 209e formed above the core filler layer 209d and being in contact with the channel layer 209c. In some implementations, the channel layer 209c can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the tunneling layer, the charge trapping layer, and the blocking layer, collectively referred to as a memory film 209b, can include ONO dielectrics (silicon Oxide-silicon Nitride-silicon Oxide). In some implementations, the channel plug 209e is surrounded by the outer dielectric layer 209a of the corresponding channel structure 208 along the Y direction.

As shown in FIG. 2B, the semiconductor device 200b can include a dielectric layer 206 stacked on top of the stack 202 along the Z direction. In some implementations, the semiconductor device 200b can also include conductive structures 210 extend through the dielectric layer 206 along the Z direction. The conductive structures 210 are connected to the corresponding channel structures 208 along the Z direction. In some implementations, the conductive structures 210 is connected to the channel structure 208 through the channel plug 209e along the first direction. In some implementations, the conductive structure 210 are formed with a self-aligned lithography process to improve the lithograph accuracy, where the conductive material of the conductive structure 210 is deposited on top of the channel plug 209e. This method removed the requirement of alignment correction step during the fabrication process, which simplify the fabrication process. In some implementations, a thickness of the dielectric layer 206 is greater than a thickness of the isolating layer 204b of the stack along the Z direction. The thicker dielectric layer 206 provides space to form the self-aligned conductive structures 210 along the Z direction.

In some implementations, the conductive structures 210 can include a first conductive structure 210a, where the first conductive structure 210a can include a first end 210a-1 and a second end 210a-2. In some implementations, a length of the first end 210a-1 of the first conductive structure 210a of the conductive structures 210 is greater than a length of the first end 208-1 of the channel structure 208 along the Y direction. The first end 210a-1 of the first conductive structure 210a is farther away from the stack 202 than the second end 210a-2 of the first conductive structure 210a. In some implementations, the first end 208-1 of the channel structure 208 is closer to the dielectric layer 206 than the second end 208-2. In some implementations, the first end 208-1 of the channel structure is the contact region between the channel plug 209e and the corresponding conductive structure 210 along the Y direction. In some implementations, as shown in FIG. 2B, a portion of the channel structure extends into the dielectric layer 206 and is connected to the conductive structures 210 along the Z direction.

The semiconductor device 200b can include an isolation structure 212. The isolating structure 212 extends through the dielectric layer 206 and at least one conductive layer of the stack 202 along the Z direction. In some implementations, the dielectric layer 206 can include a dielectric material, such as silicon oxide, silicon nitride, silicon oxynitride, or any combination thereof. In some implementations, the isolation structure 212 is between two adjacent channel structures 208 along the Y direction, and the isolation structure 212 is spaced from the channel structures 208 along the Y direction. In some implementations, the isolation structure 212 can include a dielectric material similar to, or same as the dielectric material of the dielectric layer 206. In some implementations, the isolation structure 212 can include a dielectric material, such as silicon oxide, silicon nitride, silicon oxynitride, or any combination thereof. In some implementations, a dielectric material of the isolation structure 212 can be similar to, or same as a dielectric material of the isolating layer 204b. In some implementations, the conductive structures 210 can be used as a protective structure to protect the channel structures 208 during a later process of manufacturing the semiconductor device 200b. For example, the greater length of the first end 210a-1 of the conductive structures 210a compared to the first end 208-1 of the channel structure 208 protects the channel structure 208 during the formation of the isolation structure 212.

In some implementations, a length of the first end 210a-1 of the first conductive structure 210a is greater than a length of the second end 210a-2 of the first conductive structure 210a along the Y direction. The second end 210a-2 of the first conductive structure 210a is on opposite side of the first end 210a-1 of the first conductive structure 210a and is in contact with the channel plug 209e of the channel structure 208 along the Z direction. In some implementations, as shown in FIG. 2B, the length of the second end 210a-2 of the first conductive structure 210a is equal to the length of the first end 208-1 of the channel structure 208 along the Y direction. The equal length between the second end 210a-2 of the first conductive structure 210a and the first end 208-1 of the channel structure 208 is a result of the self-alignment fabrication process of the conductive structure 210, where the conductive structure 210 is deposited on top of the channel plug 209e of the channel structure 208 to improve alignment accuracy.

In some implementations, as shown in FIG. 2B, the conductive structures 210 can include a second conductive structure 210b in contact with the corresponding isolation structure 212. In some implementations, the second conductive structure 210b is connected to the corresponding channel structure 208 along the Z direction. In some implementations, the second conductive structure 210b can include a first end 210b-1 and a second end 210b-2, where the first end 210b-1 of the second conductive structure 210b is farther away from the stack 202 than the second end 210b-2 of the second conductive structure 210b along the Z direction. The length of the first end 210a-1 of the first conductive structure 210a is greater than a length of the first end 210b-1 of the second conductive structure 210b along the Y direction. In some implementations, the second conductive structure 210b can be used as a protective structure to protect the channel structure 208 during the formation of the isolation structure 212, where a portion of the conductive material on the first end 210b-1 of the second conductive structure 210b is etched during the fabrication of the isolation structure 212. In some implementations, the isolation structure 212 is in contact with the second conductive structure 210b along the Y direction, where the isolation structure 212 is spaced from the first conductive structure 210a along the Y direction. In some implementations, the coupling-out structures are in contact with the first ends 210a-1 and 210b-1 of corresponding conductive structures 210a and 210b. A length of the first ends 210a-1 and 210b-1 of corresponding conductive structures 210a and 210b are at least two times greater than a length of an end 216-1 of the coupling-out structures 216 along the Y direction, the end 216-1 of the coupling-out structure 216 is connected to the corresponding conductive structure 210 along the first direction. For example, as shown in FIG. 2A, two adjacent of the conductive structures 210a and 210b are connected to two interconnect structures 218 through corresponding coupling-out structures 216, where the two interconnect structures 218 are spaced from each other along the X direction. The corresponding coupling-out structures 216 are in contact with the corresponding conductive structures 210a and 210b and are spaced from each other along the X direction, which requires a length of each conductive structure 210a or 210b to be at least two times greater than the length of the coupling-out structure 216 so that the two adjacent coupling-out structures 216 can be separated from each other along the X direction. In some implementations, the isolation structure 212 is in contact with at least one second conductive structure 210b, where the isolation structure 212 is spaced from the first conductive structure along the Y direction.

FIG. 2C illustrates a top view of an example semiconductor device 200c zoomed in zone B of the semiconductor device 200a of FIG. 2A. The semiconductor device 200c can be the semiconductor device 200a of FIG. 2A or a structure at an intermediate fabrication process of the semiconductor device 100 of FIG. 1.

As shown in FIG. 2C, the isolation structure 212 is connected to the second conductive structure 210b along the Y direction, and the second conductive structure 210b are partially surrounded the isolation structure 212. The coupling-out structures 216 are connected to the second conductive structure 210b along the Z direction. In some implementations, a length of the first end 210b-1 of the second conductive structure 210b is at least two times greater than the length of the end 216-1 of the coupling-out structure 216 along the X direction. In some implementations, the second conductive structure 210b can be used as a protective structure to protect the channel structure 208 during the formation of the isolation structure 212. As shown in FIG. 2C, a portion of the conductive material on the first end 210b-1 of the second conductive structure 210b is etched during the fabrication of the isolation structure 212, where the second conductive structure 210b is connected to the isolation structure 212 along the Y direction. The conductive structure 210 can include two separate locations 217a, 217b for the coupling-out structure 216 as shown in FIG. 2C. In some implementations, one of the two separate locations 217a, 217b on the conductive structure 210 is occupied by the coupling-out structure 216 and a remaining location of the two separate locations will stay empty. For example, as shown in FIG. 2C, the second conductive structure 210b includes two locations 217a and 217b for the coupling-out structure 216, where the coupling-out structure 216 occupies the location 217a of the two locations, and the location 217b remains empty on the second conductive structure 210b as shown in FIG. 2C.

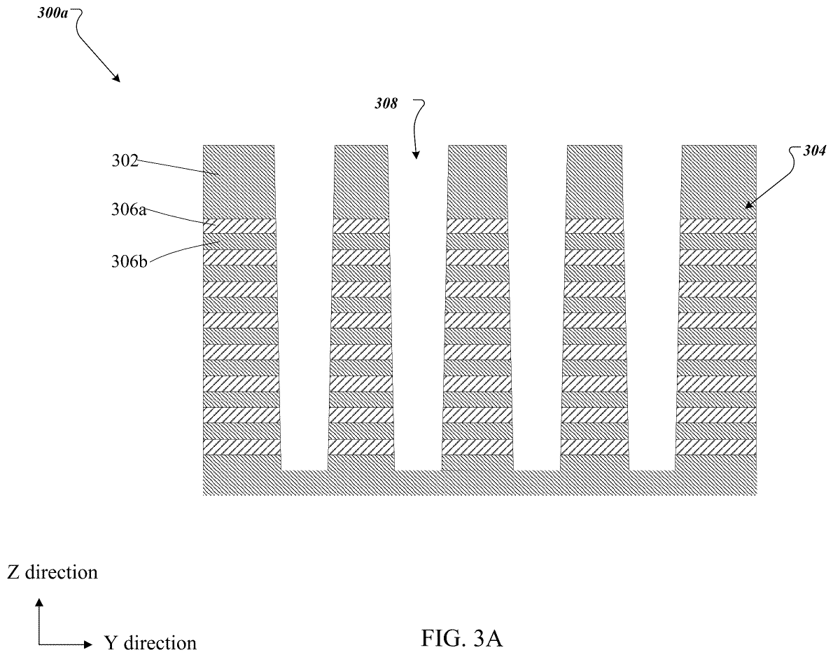

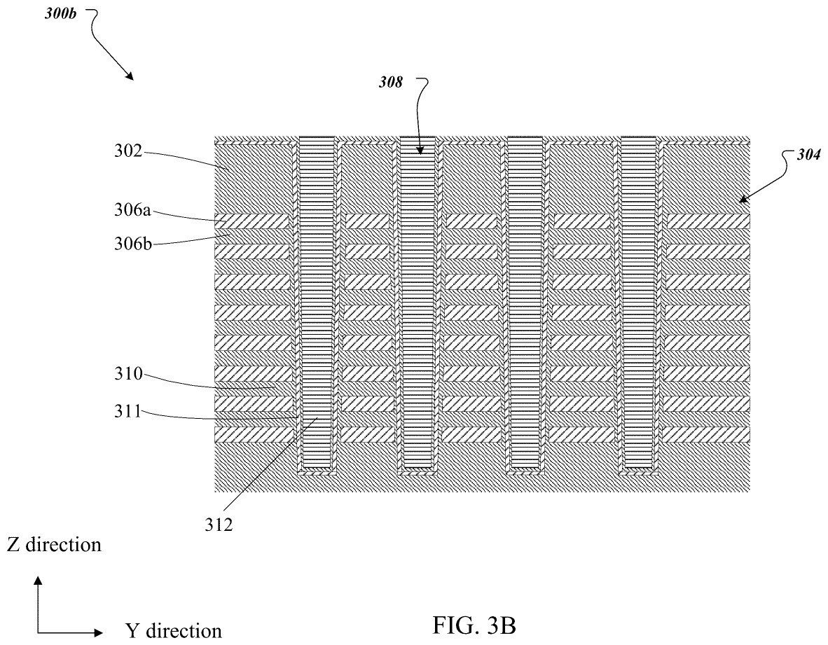

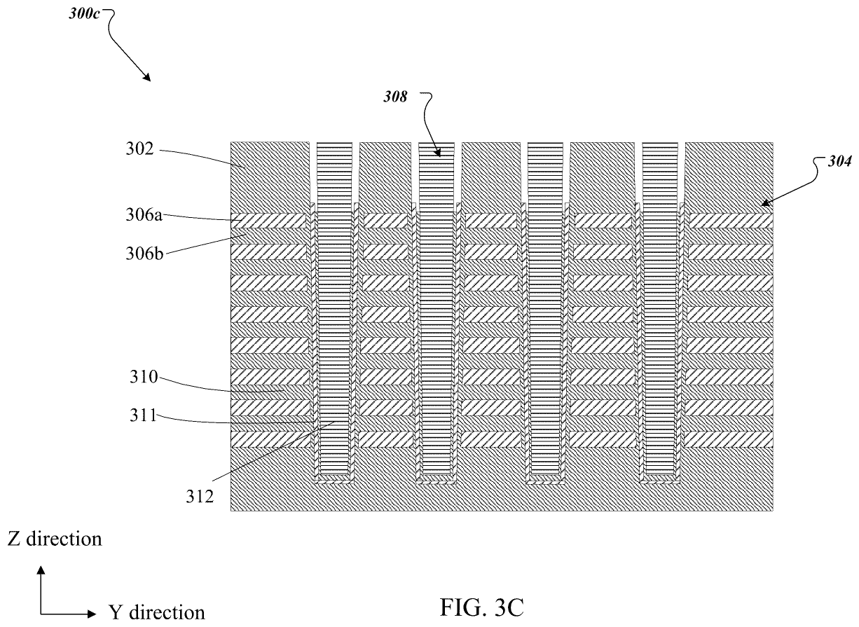

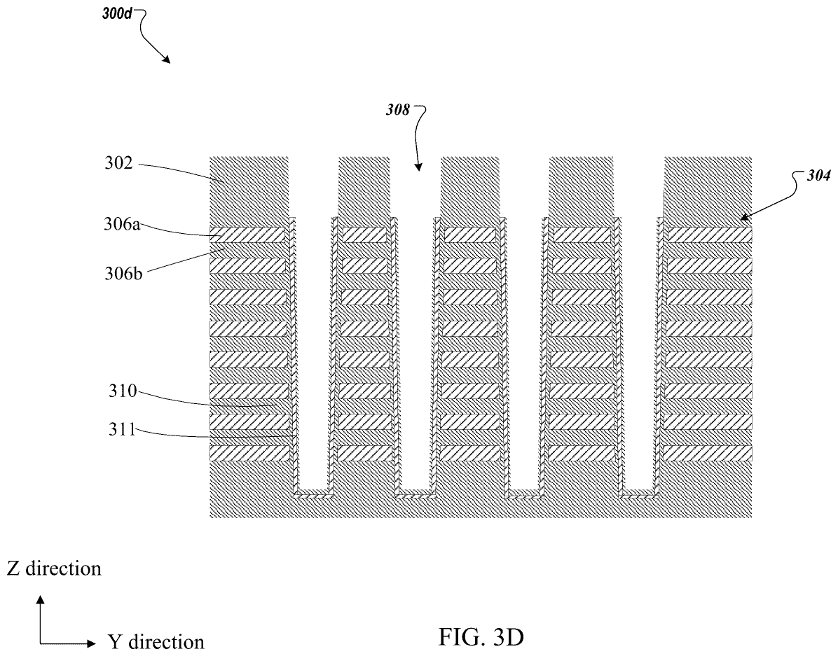

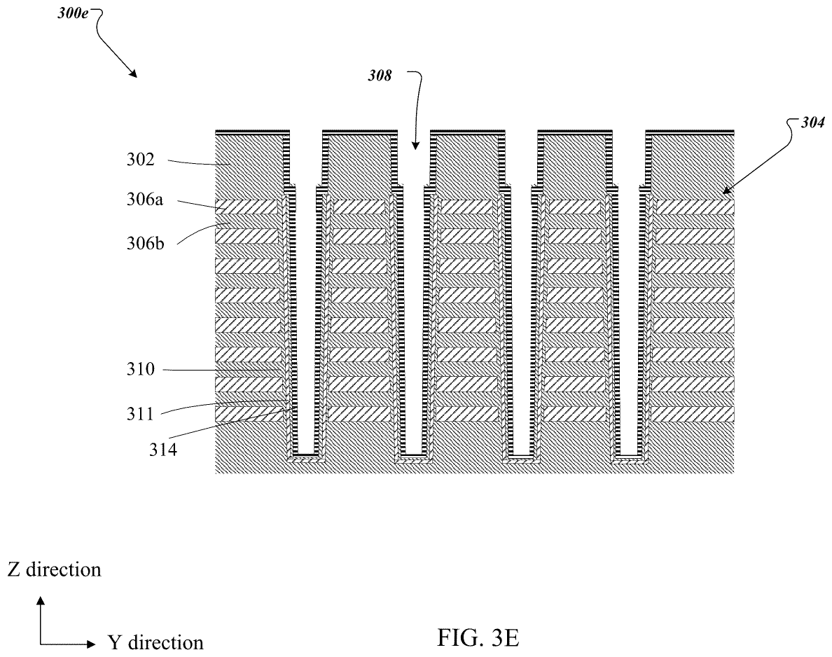

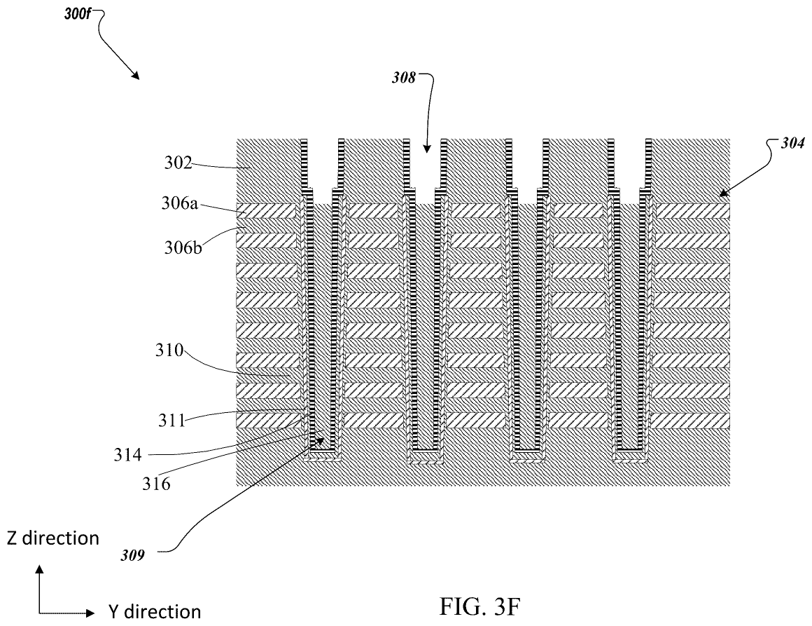

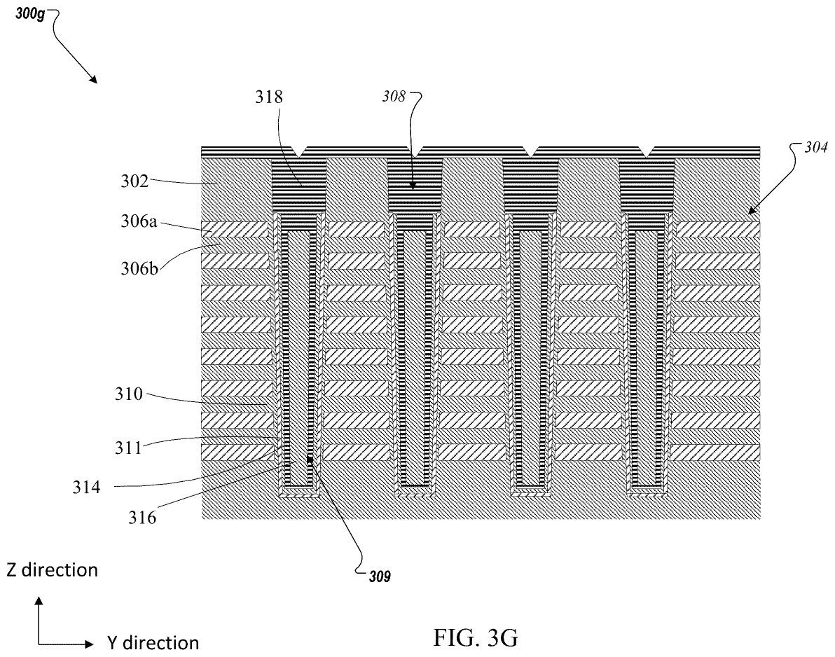

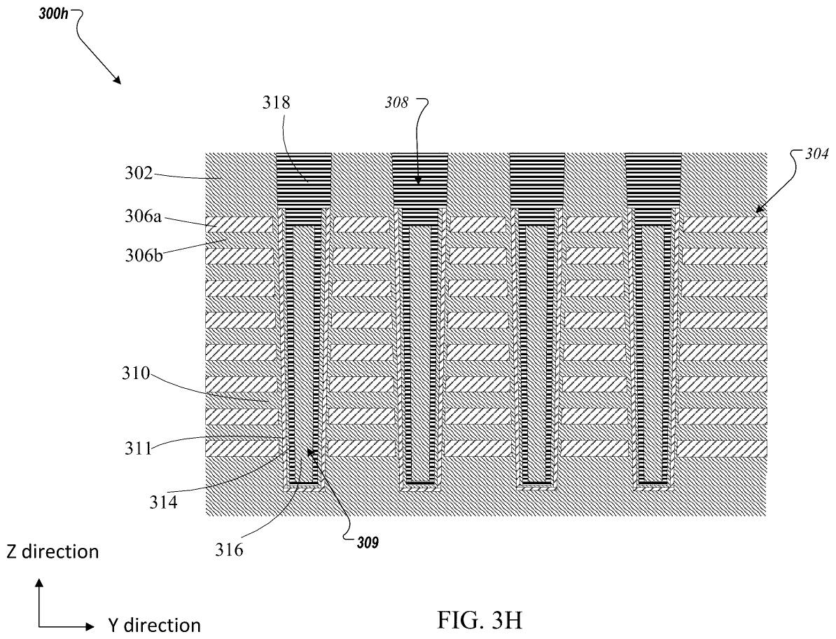

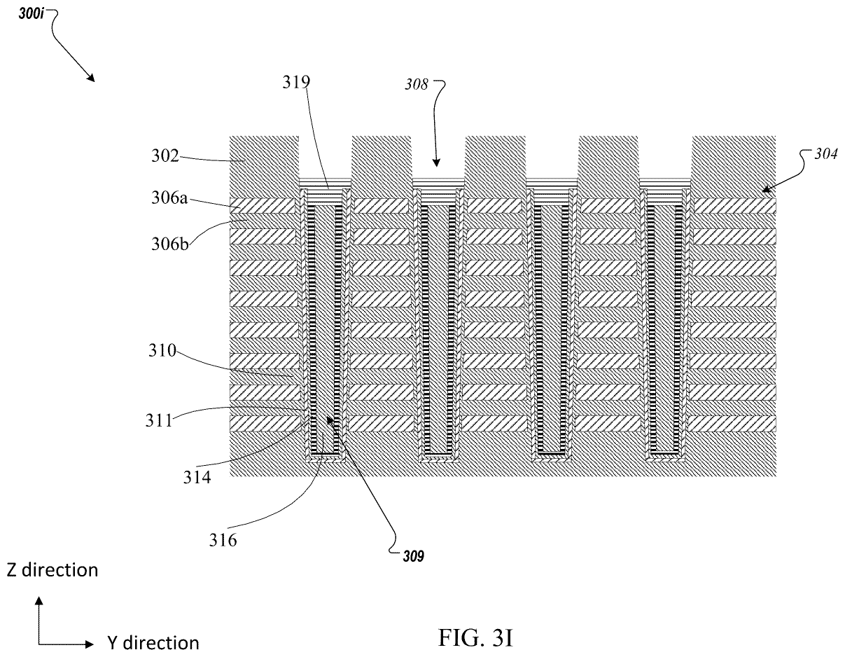

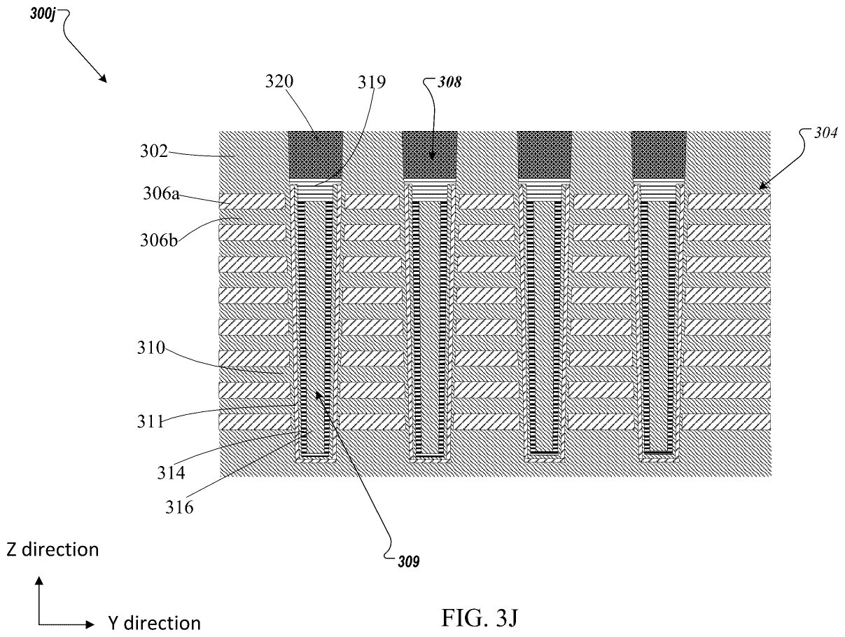

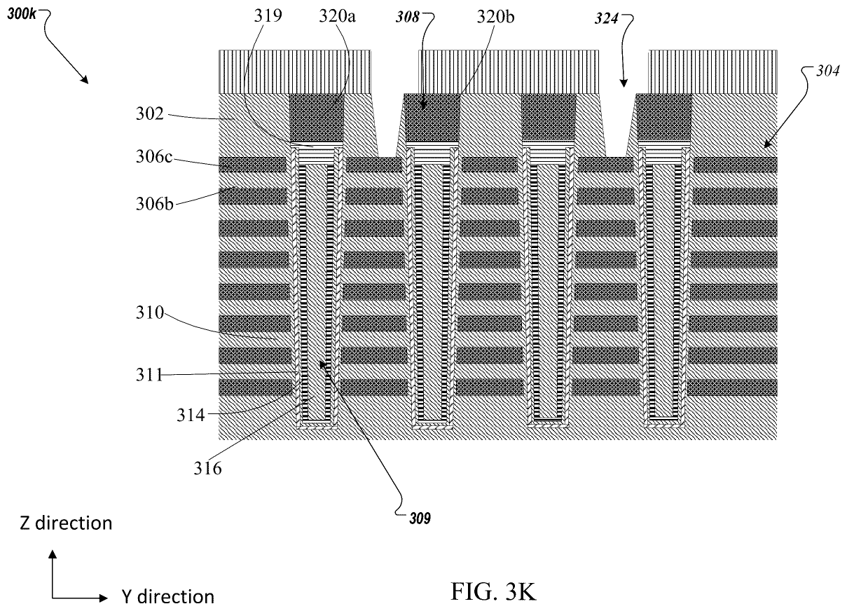

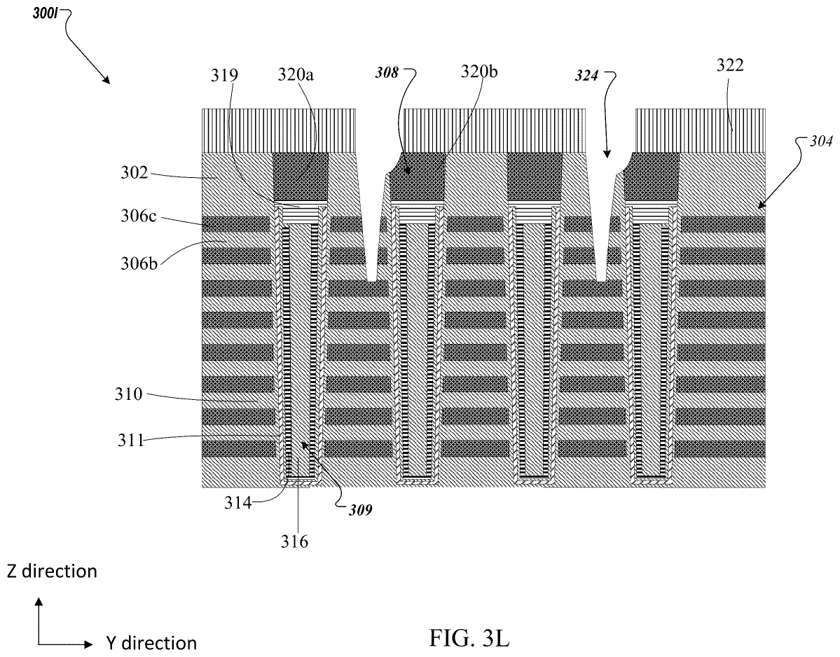

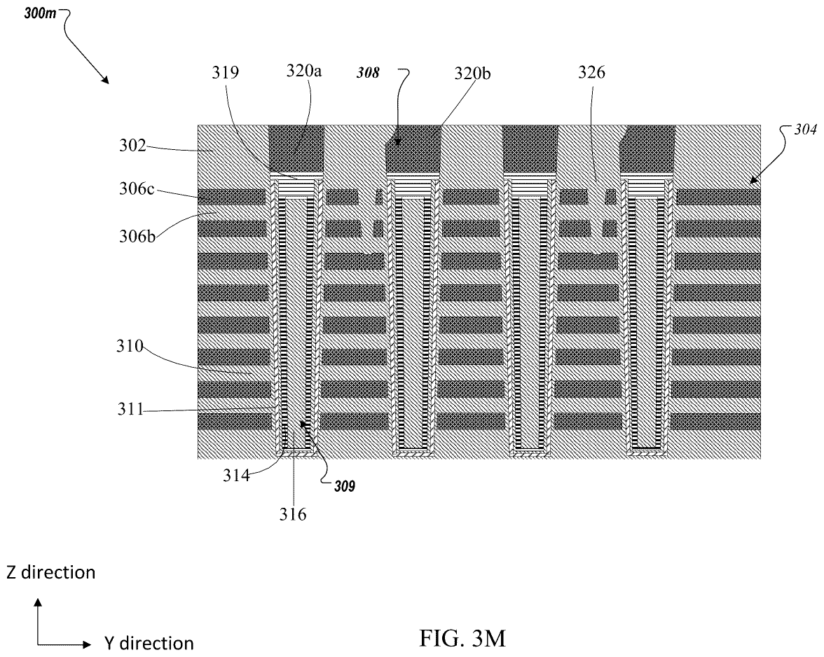

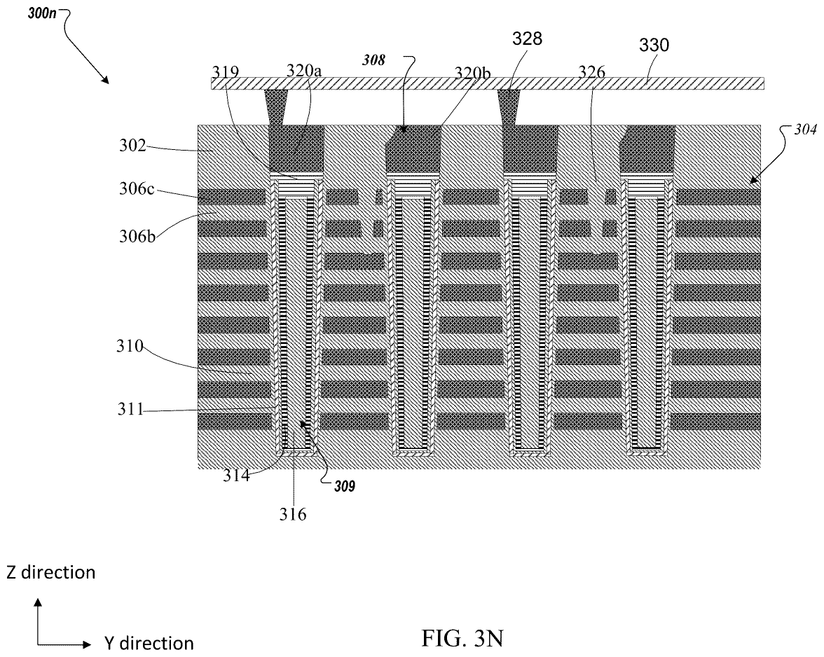

FIGS. 3A-3N illustrate an example process of fabricating a semiconductor device, such as the semiconductor device 200a as illustrated in FIG. 2A. FIGS. 3A-3N show cross-sectional views of example semiconductor structures at various stages of the fabrication process.

As shown in FIG. 3A, a semiconductor structure 300a is formed. The semiconductor structure 300a includes a dielectric layer 302 and a stack 304 of sacrificial layers 306a and isolating layers 306b that alternate with each other along a vertical direction (e.g., Z direction). The stack 304 is stacked on the dielectric layer 302 along the Z direction. The semiconductor structure 300a also includes first spaces 308, which can be formed by etching through the dielectric layer 302 and the stack 304 along the first direction.

FIG. 3B illustrates a semiconductor structure 300b, which can be formed by depositing an outer dielectric layer 311 and memory film 310 on the inner wall of the first spaces 308 and filling a remaining portion of the first spaces 308 with a dielectric material to form a first dielectric body 312. In some implementations, the outer dielectric layer 311 can include a dielectric material such as silicon oxide. In some implementations, a dielectric material of the outer dielectric layer 311 is different compared to a dielectric material of the first dielectric body 312. In some implementations, the memory film 310 can include a tunneling layer, the charge trapping layer, and the blocking layer and the memory film 310 can include ONO dielectrics such as silicon Oxide-silicon Nitride-silicon Oxide.

FIG. 3C illustrates a semiconductor structure 300c, which can be formed by removing a portion of the outer dielectric layer 311 and the memory film 310 in the first spaces 308 with a wet etching process.

FIG. 3D illustrates a semiconductor structure 300d, which can be formed by removing the first dielectric body 312 in the first spaces 308 through an etching process.

FIG. 3E illustrates a semiconductor structure 300e, which can be formed by depositing a semiconductor layer 314 on the side wall of the first spaces 308 and a surface of the semiconductor structure 300d. The surface of the semiconductor structure is closer to the dielectric layer 302. In some implementations, the semiconductor layer 314 can include a semiconductor material such as polysilicon.

FIG. 3F illustrates a semiconductor structure 300f, which can be formed by performing a planarization process, such as chemical mechanical polishing (CMP), to remove the excess semiconductor material in the semiconductor layer 314 on top of the semiconductor structure 300e. The semiconductor structure 300f can also include a second dielectric body 316 which can be formed by depositing a dielectric material (e.g., silicon oxide) in a portion of the first spaces 308 to form the second dielectric body 316. In some implementations, the dielectric body 316, the semiconductor layer 314, the memory layer 310, and the outer dielectric layer 311 can be used as a channel structure 309 for the memory device.

FIG. 3G illustrates a semiconductor structure 300g, which can be formed by depositing a semiconductor material (e.g., poly-Si) in the first spaces 308 and on a surface of the semiconductor structure 300f to form a semiconductor body 318. The surface of the semiconductor structure 300f is closer to the dielectric layer 302 than the stack 304.

FIG. 3H illustrates a semiconductor structure 300h, which can be formed by performing a planarization process, such as chemical mechanical polishing (CMP), to remove the excess semiconductor material in the semiconductor body 318 on top of the semiconductor structure 300e.

FIG. 3I illustrates a semiconductor structure 300i, which can be formed by etching a portion of the semiconductor body 318 in the first spaces 308. In some implementations, a remaining portion of the semiconductor body 318 can be used as a channel plug 319 for the channel structure 309. In some implementations, a portion of the channel plug 319 of the channel structure 309 is surrounded by the outer dielectric layer 311. The etching portion of the semiconductor body 318 in the first spaces 308 can be used to form conductive structures without any further alignment steps, which can ensure the conductive structures are connected to the corresponding channel structures 309 through the channel plug 319.

FIG. 3J illustrates a semiconductor structure 300j, which can be formed by depositing a conductive material in the etched portion of the first spaces 308 to form conductive structures 320. In some implementations, as shown in FIG. 3J, the conductive structures 320 are formed with a self-alignment process, which does not require additional alignment process. This simplifies the fabrication steps and ensures a high-quality contact between the conductive structures 320 and the corresponding channel structures 309.

FIG. 3K illustrates a semiconductor structure 300k, which can be formed by replacing a dielectric material in the sacrificial layers 306a with a conductive material to form conductive layers 306c in the stack 304. The semiconductor structure 300k can include a sacrificial layer 322, which can be formed by depositing a sacrificial material on top of the semiconductor structure 300j. The semiconductor structure 300k also includes one or more second spaces 324. The one or more second spaces 324 are formed by etching through a portion of the sacrificial layer 322 and the dielectric layer 302 along the Z direction. In some implementations, the conductive structures 320 include first conductive structures 320a and second conductive structures 320b. The one or more second spaces 324 are connected to corresponding second conductive structures 320b of the semiconductor structure 300k.

FIG. 3L illustrates a semiconductor structure 300l, which can be formed by etching through at least one conductive layer 306c of the stack 304 and a portion of the second conductive structures 320b in the dielectric layer from an end of the one or more second spaces 324 along the Z direction. The conductive structure 320b is used as a protective structure during the etching of the stack 304, where a portion of the conductive material of the conductive structure 320b is etched during the fabrication process to protect the channel structure 309. The end of one or more second spaces 324 is closer to the stack 304 than a surface of the dielectric layer 302.

FIG. 3M illustrates a semiconductor structure 300m, which can be formed by removing the sacrificial layer 322 and depositing a dielectric material into the one or more second spaces 324 to form isolation structures 326. In some implementations, the dielectric material of the isolation structures 326 is similar to, or same as the dielectric material of the dielectric layer 302 and the dielectric material of the isolating layer 306b of the stack 304.

FIG. 3N illustrates a semiconductor structure 300n, which can be formed by depositing a conductive material on top of the conductive structures 320 to form coupling-out structures 328, where the conductive structures 320 in the dielectric layer 302 are connected to interconnect structures 330 through the coupling-out structures 328.

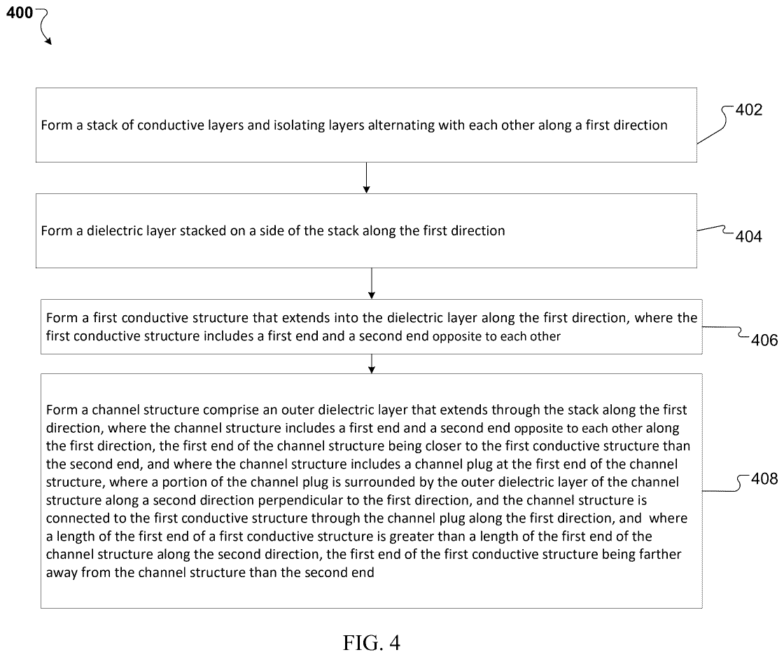

FIG. 4 illustrates a flow chart of an example process 400. The process 400 can be performed to form a semiconductor device (e.g., the semiconductor device 200a illustrated by FIG. 2A). The process 400 can be described in view of FIGS. 3A-3N . The process 400 can include one or more steps of the fabrication process of forming the semiconductor structures in FIGS. 3A-3N . It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a stack (e.g., the stack 304 of FIG. 3A) of conductive layers (e.g., the conductive layers 306c of FIG. 3K) and isolating layers (e.g., the isolating layers 306b of FIG. 3A) alternating with each other along a first direction (e.g., the Z direction) is formed.

At operation 404, a dielectric layer (e.g., the dielectric layer 302 of FIG. 3A) stacked on a side of the stack along the first direction is formed.

At operation 406, a first conductive structure (e.g., the first conductive structure 320a of FIG. 3K) that extends into the dielectric layer along the first direction is formed, where the first conductive structure includes a first end and a second end opposite to each other.

At operation 408, a channel structure (e.g., the channel structure 309 of FIG. 3F) include an outer dielectric layer (e.g., the outer dielectric layer 311 of FIG. 3B) that extends through the stack along the first direction, where the channel structure includes a first end and a second end opposite to each other along the first direction, the first end of the channel structure being closer to the first conductive structure than the second end, and where the channel structure includes a channel plug (e.g., the channel plug 319 of FIG. 3I) at the first end of the channel structure, where a portion of the channel plug is surrounded by the outer dielectric layer of the channel structure along a second direction perpendicular to the first direction, and the channel structure is connected to the first conductive structure through the channel plug along the first direction, and where a length of the first end of a first conductive structure is greater than a length of the first end of the channel structure along the second direction, the first end of the first conductive structure being farther away from the channel structure than the second end.

In some implementations, forming the first conductive structure includes forming a stack of sacrificial layers (e.g., the sacrificial layers 306a of FIG. 3A) and isolating layers alternating with other along the first direction; depositing a dielectric material on the side of the stack to from the dielectric layer, where the dielectric layer stacked on the side of the stack along the first direction; etching a portion of the dielectric layer and the stack along the first direction to from first space (e.g. the first spaces 308 of FIG. 3A); forming the channel structure in a portion of the first spaces along the first direction, where the channel structure includes a channel plug at the first end of the channel structure; filling a conductive material into a remaining portion of the first space to from the first conductive structure; and replacing a dielectric material in the sacrificial layers with a conductive material to form conductive layers.

In some implementations, the semiconductor device further includes an isolation structure (e.g., the isolation structure 326 of FIG. 3M) that extends through the dielectric layer and at least one conductive layer of the stack along the first direction, and where forming the isolation structure includes etching through the dielectric layer to form a second space (e.g., the one or more second spaces 324 of FIG. 3K), where the second space is in contact with a corresponding conductive structure; deepening the second space by etching through at least one conductive layer of the stack from an end of the second space along the first direction and etching a portion of the corresponding conductive structure to from a second conductive structure, the end of the second space being connected to the stack; and filling a dielectric material into the second space to form the isolation structure, where the isolation structure is between two adjacent channel structures along the second direction.

In some implementations, the operation further includes forming a coupling-out structure (e.g., the coupling-out structure 328 of FIG. 3N), where the first conductive structure in the dielectric layer is connected to an interconnect structure (e.g., the interconnect structures 330 of FIG. 3N) through the coupling-out structure.

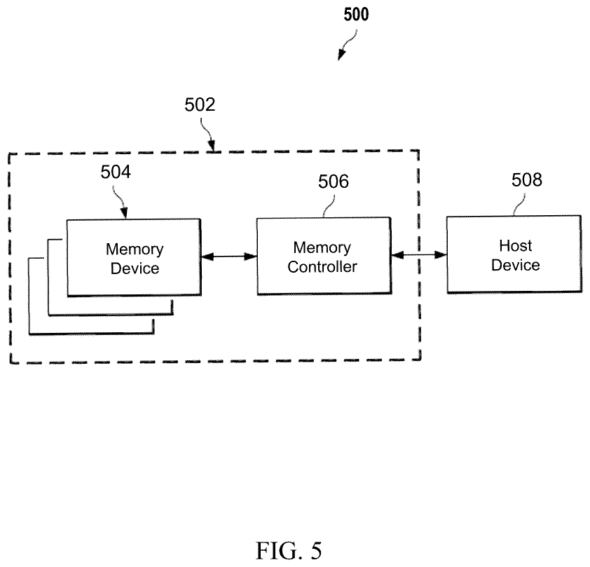

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed in the present disclosure, such as a memory device (e.g., a NAND Flash memory) as shown in FIG. 1 and FIGS. 2A-2C . Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a stack of conductive layers and isolating layers alternating with each other along a first direction;
a dielectric layer stacked on a side of the stack along the first direction;
a first conductive structure that extends into the dielectric layer along the first direction, wherein the first conductive structure comprises a first end and a second end opposite to each other; and
a channel structure comprises an outer dielectric layer that extends through the stack along the first direction, wherein the channel structure comprises a first end and a second end opposite to each other along the first direction, the first end of the channel structure being closer to the first conductive structure than the second end, and
wherein the channel structure comprises a channel plug at the first end of the channel structure, wherein a portion of the channel plug is surrounded by the outer dielectric layer of the channel structure along a second direction perpendicular to the first direction, and the channel structure is connected to the first conductive structure through the channel plug along the first direction, and
wherein a length of the first end of a first conductive structure is greater than a length of the first end of the channel structure along the second direction, the first end of the first conductive structure being farther away from the channel structure than the second end.

2. The semiconductor device of claim 1, wherein a thickness of the dielectric layer is greater than a thickness of the isolating layers of the stack along the first direction.

3. The semiconductor device of claim 1, further comprising:
an isolation structure that extends through the dielectric layer and at least one conductive layer of the stack along the first direction.

4. The semiconductor device of claim 3, wherein the isolation structure is between two adjacent channel structures along the second direction.

5. The semiconductor device of claim 1, wherein, along the second direction, the length of the first end of the first conductive structure is greater than a length of the second end of the first conductive structure, the second end of the first conductive structure being on opposite side of the first end of the first conductive structure along the first direction.

6. The semiconductor device of claim 1, wherein the length of the first end of the channel structure is equal to the length of the second end of the first conductive structure along the second direction.

7. The semiconductor device of claim 1, wherein the semiconductor device comprises a second conductive structure having a first end and a second end along the first direction connected to the corresponding channel structure, and wherein the length of the first end of the first conductive structure is greater than a length of a first end of the second conductive structure along the second direction, the first end of the second conductive structure being farther away from the stack than the second end of the second conductive structure.

8. The semiconductor device of claim 1, wherein the first conductive structure in the dielectric layer is connected to an interconnect structure through a coupling-out structure.

9. The semiconductor device of claim 8, wherein a length of the first end of the first conductive structure is at least two times greater than a length of the coupling-out structure along the second direction.

10. A semiconductor device, comprising:
a stack of conductive layers and isolating layers alternating with each other along a first direction;
a dielectric layer stacked on a side of the stack along the first direction;
a first conductive structure that extends into the dielectric layer along the first direction, wherein the first conductive structure comprises a first end and a second end opposite to each other; and
a channel structure comprise an outer dielectric layer that extends through the stack along the first direction connected to the first conductive structure, wherein the channel structure comprises a first end and a second end opposite to each other along the first direction, the first end of the channel structure being closer to the first conductive structure than the second end, and
wherein a length of the first end of a first conductive structure is greater than a length of the first end of the channel structure along a second direction perpendicular to the first direction, the first end of the first conductive structure being farther away from the stack than the second end, and
wherein the length of the first end of the channel structure is equal to a length of the second end of the first conductive structure along the second direction, the second end of the first conductive structure being on opposite side of the first end of the first conductive structure along the first direction.

11. The semiconductor device of claim 10, wherein a thickness of the dielectric layer is greater than a thickness of the isolating layers of the stack along the first direction.

12. The semiconductor device of claim 10, further comprising:
an isolation structure that extends through the dielectric layer and at least one conductive layer of the stack along the first direction, wherein the isolation structure is between two adjacent channel structures along the second direction.

13. The semiconductor device of claim 10, wherein the channel structure comprises a channel plug at the first end of the channel structure, wherein a portion of the channel plug is surrounded by the outer dielectric layer of the corresponding channel structure along a second direction perpendicular to the first direction, and wherein the channel structure is connected to the first conductive structure through the channel plug along the first direction.

14. The semiconductor device of claim 10, wherein the semiconductor device comprises a second conductive structure having a first end and a second end along the first direction connected to the corresponding channel structure, and wherein the length of the first end of the first conductive structure is greater than a length of a first end of the second conductive structure along the second direction, the first end of the second conductive structure being farther away from the stack than the second end of the second conductive structure.

15. The semiconductor device of claim 10, wherein the first conductive structure in the dielectric layer is connected to an interconnect structure through a coupling-out structure.

16. The semiconductor device of claim 15, wherein a length of the first end of the first conductive structure is at least two times greater than a length of the coupling-out structure along the second direction.

17. A method of forming a semiconductor device, wherein the method comprises:
forming a stack of conductive layers and isolating layers alternating with each other along a first direction;
forming a dielectric layer stacked on a side of the stack along the first direction;
forming a first conductive structure that extends into the dielectric layer along the first direction, wherein the first conductive structure comprises a first end and a second end opposite to each other; and
forming a channel structure comprise an outer dielectric layer that extends through the stack along the first direction, wherein the channel structure comprises a first end and a second end opposite to each other along the first direction, the first end of the channel structure being closer to the first conductive structure than the second end, and
wherein the channel structure comprises a channel plug at the first end of the channel structure, wherein a portion of the channel plug is surrounded by the outer dielectric layer of the channel structure along a second direction perpendicular to the first direction, and the channel structure is connected to the first conductive structure through the channel plug along the first direction, and
wherein a length of the first end of a first conductive structure is greater than a length of the first end of the channel structure along the second direction, the first end of the first conductive structure being farther away from the channel structure than the second end.

18. The method of claim 17, wherein forming the first conductive structure comprises:
forming a stack of sacrificial layers and isolating layers alternating with other along the first direction;
depositing a dielectric material on the side of the stack to from the dielectric layer, wherein the dielectric layer stacked on the side of the stack along the first direction;
etching a portion of the dielectric layer and the stack along the first direction to from first space;
forming the channel structure in a portion of the first spaces along the first direction, wherein the channel structure comprises a channel plug at the first end of the channel structure;
filling a conductive material into a remaining portion of the first space to from the first conductive structure; and
replacing a dielectric material in the sacrificial layers with a conductive material to form conductive layers.

19. The method of claim 17, wherein the semiconductor device further comprises an isolation structure that extends through the dielectric layer and at least one conductive layer of the stack along the first direction, and wherein forming the isolation structure comprises:
etching through the dielectric layer to form a second space, wherein the second space is in contact with a corresponding conductive structure;
deepening the second space by etching through at least one conductive layer of the stack from an end of the second space along the first direction and etching a portion of the corresponding conductive structure to from a second conductive structure, the end of the second space being connected to the stack; and
filling a dielectric material into the second space to form the isolation structure, wherein the isolation structure is between two adjacent channel structures along the second direction.

20. The method of claim 17, further comprising:
forming a coupling-out structure, wherein the first conductive structure in the dielectric layer is coupled to an interconnect structure through the coupling-out structure.
